(19) United States
(12) Patent Application Publication
(10) Pub. No.: US 2014/0352784 A1
(43) Pub. Date: Dec. 4, 2014

(54) PHOTOLUMINESCENCE WAVELENGTH TUNABLE MATERIAL AND ENERGY HARVESTING USING METAL NANOPARTICLE-GRAPHENE OXIDE COMPOSITE

(71) Applicant: KOREA INSTITUTE OF SCIENCE AND TECHNOLOGY, Seoul (KR)

(72) Inventors: Jae Hun Kim, Seoul (KR); Seong Chan Jun, Seoul (KR); Ju Yeong Oh, Gimpo-si (KR); Seok Lee, Seoul (KR); Taikjin Lee, Seoul (KR); Deok Ha Woo, Seoul (KR); Sun Ho Kim, Seoul (KR); Chul Ki Kim, Samcheok-si (KR); Juhwan Lim, Seoul (KR)

(73) Assignee: KOREA INSTITUTE OF SCIENCE AND TECHNOLOGY, Seoul (KR)

(21) Appl. No.: 14/042,978

(22) Filed: Oct. 1, 2013

(30) Foreign Application Priority Data
May 28, 2013 (KR) 10-2013-0060300

(51) Int. Cl. H01L 31/055; H01L 31/18

(52) U.S. Cl. CPC H01L 31/055; H01L 31/18
USPC 136/257; 252/301.16; 438/69

(57) ABSTRACT

A photoluminescence wavelength tunable material may include a composite including a graphene oxide layer and metal nanoparticles attached on the graphene oxide layer. By attaching the metal nanoparticles to the graphene oxide, the photoluminescence wavelength (i.e., the color of emitted light) of the graphene oxide may be tuned while maintaining the structure and physical properties of graphene oxide. The photoluminescence wavelength tunable material may be applied to an energy harvesting device such as a solar cell which exhibits high efficiency with less loss of light.

### CROSS-REFERENCE TO RELATED APPLICATION

This application claims priority to Korean Patent Application No. 10-2013-0060300, filed on May 28, 2013, and all the benefits accruing therefrom under 35 U.S.C. §119, the contents of which in its entirety are herein incorporated by reference.

### BACKGROUND

1. Field

Embodiments relate to energy harvesting, more particularly to a photoluminescence wavelength tunable composite material wherein metal nanoparticles are bound to graphene oxide and applications thereof.

2. Description of the Related Art

To use a solar cell, the wavelength of the light incident from the sun should match very well with the band gap of the active layer of the solar cell. If the light's energy is lower than the band gap, the light cannot be absorbed into the solar cell but passes through it. Conversely, if the light's energy is higher than the band gap, excess energy that does not participate in energy conversion by the solar cell remains. This excess energy is mostly converted to thermal energy and, thus, the efficiency of the solar cell is decrease greatly.

Accordingly, use of a converter capable of tuning the wavelength of the light incident on the active layer of the solar cell is proposed as a way of improving the solar cell's efficiency. For example, Korean Patent Application Publication No. 10-2011-0096943 discloses a light-selective transmission type solar cell using a porous film capable of selectively transmitting light of a specific wavelength from sunlight.

### SUMMARY

An aspect of the present disclosure is directed to providing a photoluminescence wavelength tunable material wherein metal nanoparticles are bound to graphene oxide, a method for preparing same and an optical device using the photoluminescence wavelength tunable material.

According to an embodiment, there is provided a photoluminescence wavelength tunable material including a composite including a graphene oxide layer and metal nanoparticles attached on the graphene oxide layer.

According to an embodiment, there is provided an optical device including the photoluminescence wavelength tunable material. For example, the optical device may be a solar cell and the solar cell may include an active layer configured to produce electric energy using the light emitted by the photoluminescence wavelength tunable material.

According to an embodiment, there is provided a method for preparing a photoluminescence wavelength tunable material, including: forming a graphene oxide layer; and attaching metal nanoparticles to the graphene oxide layer to form a composite comprising the graphene oxide layer and metal nanoparticles.

### BRIEF DESCRIPTION OF THE DRAWINGS

The above and other aspects, features and advantages of the disclosed exemplary embodiments will be more apparent from the following detailed description taken in conjunction with the accompanying drawings in which:

FIG. 1a shows a schematic view and a transmission electron microscopic (TEM) image of a graphene oxide layer;

FIG. 1b shows a schematic view and a TEM image of a composite wherein metal nanoparticles are bound to the graphene oxide layer of FIG. 1a;

FIG. 2 schematically shows atomic arrangement of a composite wherein metal nanoparticles are bound to graphene oxide;

FIG. 3 shows a flowchart illustrating a method for preparing a photoluminescence wavelength tunable solar cell using a composite according to an embodiment;

FIG. 4a shows photoluminescence wavelength of graphene oxide samples;

FIG. 4b shows photoluminescence wavelength of composites wherein palladium (Pd) nanoparticles are attached to the graphene oxide sample of FIG. 4a; and

FIG. 4c is a CIE (International Commission on Illumination) chromaticity diagram showing the change in photoluminescence wavelength shown in FIGS. 4a and 4b.

### DETAILED DESCRIPTION

Exemplary embodiments now will be described more fully hereinafter with reference to the accompanying drawings, in which exemplary embodiments are shown.

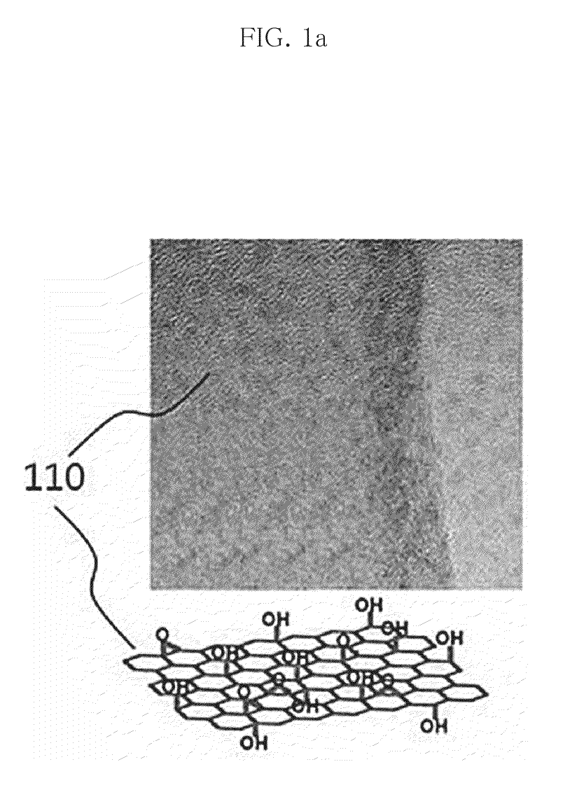

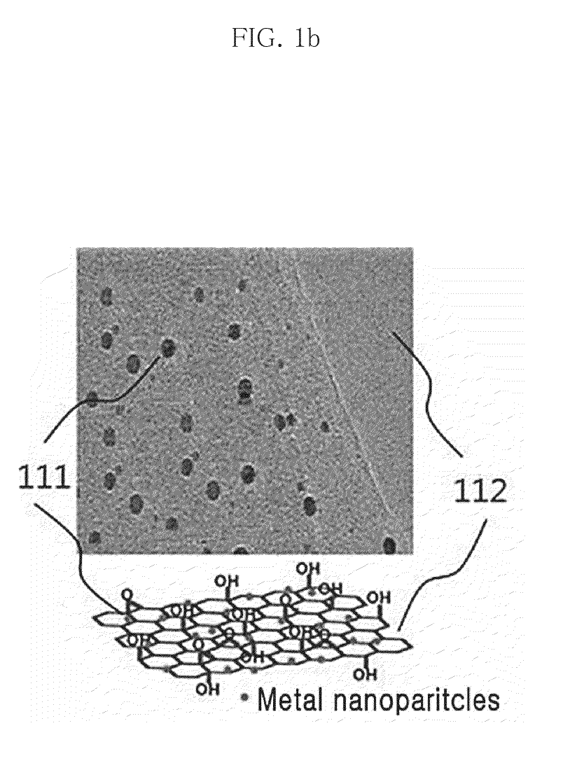

FIG. 1a shows a schematic view and a transmission electron microscopic (TEM) image of a graphene oxide layer and FIG. 1b shows a schematic view and a TEM image of a composite wherein metal nanoparticles are bound to the graphene oxide layer of FIG. 1a.

Graphene oxide, which consists of a single layer of carbon atoms, has a photoluminescence (PL) characteristic in a broad visible range. When light of a predetermined wavelength is incident on graphene oxide, the graphene oxide absorbs the light and then emits light. The light emitted from the graphene oxide may be of various colors with various wavelengths. The photoluminescence wavelength (i.e., the color of the emitted light) may be varied by changing the physical and/or electrical structure of the graphene oxide.

A photoluminescence wavelength tunable material according to an exemplary embodiment may include a composite of graphene oxide and metal nanoparticles. To form the composite, a graphene oxide layer 110 consisting of graphene oxide may be first prepared as shown in FIG. 1a. Then, one or more metal nanoparticles 111 may be attached to the graphene oxide layer 110 to form graphene oxide-metal nanoparticle composite 112.

The metal nanoparticles 111 attached to the graphene oxide layer 110 serve to change the photoluminescence characteristic of graphene oxide. The metal nanoparticles 111 may consist of palladium (Pd), gold (Au), silver (Ag), titanium (Ti), chromium (Cr), aluminum (Al), copper (Cu), europium (Eu), erbium (Eb) or other suitable metal. The metal nanoparticles 111 may also consist of titanium oxide (TiO₂), aluminum oxide (Al₂O₃) or other suitable metal oxide. The metal nanoparticles 111 may include particles of various sizes and the nanoparticles 111 may be uniform or irregular in size. For example, the metal nanoparticles 111 may have diameters ranging from a few angstroms (A) to tens of thousands of nanometers (nm), without being limited to particular size.

The metal nanoparticles 111 may be attached to the graphene oxide layer 110 by means of various chemical, physical and/or electrical methods. For example, the metal atoms or molecules of the metal nanoparticles 111 may be chemically bonded to the graphene oxide or the metal nanoparticles 111 may be physically coated on the graphene oxide layer 110. Alternatively, the metal nanoparticles 111 may be attached to the graphene oxide layer 110 by other various electrical or mechanical methods not described herein.

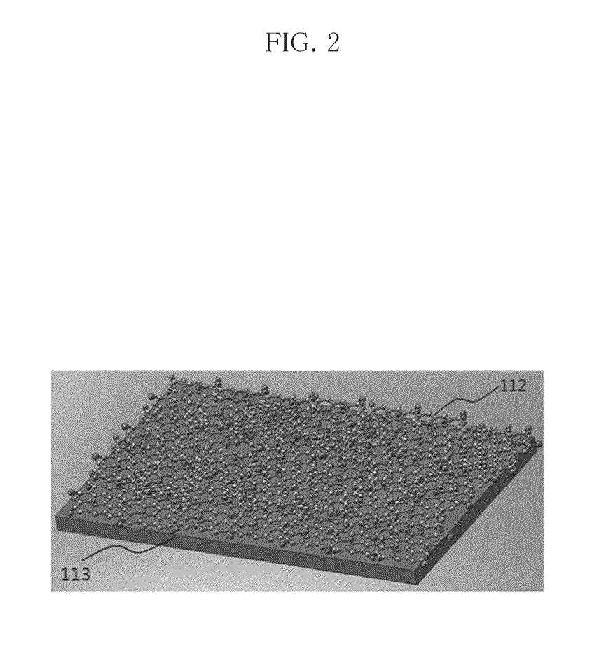

FIG. 2 schematically shows atomic arrangement of a composite wherein metal nanoparticles are bound to graphene oxide according to an exemplary embodiment. The composite 112 may exhibit shift toward longer wavelength (i.e., red shift) or shorter wavelength (i.e., blue shift), as compared to the photoluminescence wavelength of pure graphene oxide, depending on the material of the metal nanoparticles attached on the graphene oxide. As exemplary embodiments, the blue shift of the photoluminescence wavelength of graphene oxide owing to attachment of palladium (Pd) nanoparticles will be described. However, this is only exemplary and nanoparticles of other metals such as gold (Au), europium (Eu), etc. may be used in other exemplary embodiments.

In an exemplary embodiment, the degree of change of photoluminescence wavelength may be controlled by the proportion of the metal nanoparticles to the graphene oxide in the graphene oxide-metal nanoparticle composite 112. For example, it can be expected that the degree of change of photoluminescence wavelength may increase as the proportion of the metal nanoparticles in the graphene oxide-metal nanoparticle composite 112 is higher.

In an exemplary embodiment, after the graphene oxide-metal nanoparticle composite 112 is formed, the photoluminescence wavelength may be further adjusted by inducing structural change by treating the composite 112 with heat and/or plasma.

For example, if the composite 112 is heat-treated at about 75° C. or above, the oxygen functional groups attached to graphene oxide (e.g., ethyl, epoxy, carbonyl, etc.) may be reduced. Each oxygen functional group has a unique temperature at which the functional group is reduced (For example, the reduction temperature of C═O is about 150° C.). Therefore, the oxygen functional groups may be reduced by heating the composite 112 above the reduction temperature and, as a result, the photoluminescence wavelength of graphene oxide may be changed. The degree of reduction of the oxygen functional groups may be controlled by controlling the heat treatment temperature.

If the composite 112 is treated with oxygen (O₂) plasma or oxidized by heating, red shift may occur as carbons having sp³ orbitals increase in the graphene. Conversely, if the composite 112 is reduced, blue shift may occur as carbons having sp² orbitals increase. That is to say, the proportion of sp³ carbons and sp² carbons in the graphene oxide layer may be changed by treating with heat and/or plasma and, as a result thereof, the photoluminescence wavelength of graphene oxide may be changed.

In addition to the reduction of the oxygen functional groups or the change in the orbitals of carbons described above, the photoluminescence wavelength may be changed as a result of electron transfer, oxygen absorption, etc. caused by the heat and/or plasma treatment.

As shown in FIG. 2, the graphene oxide-metal nanoparticle composite 112 may be positioned on a substrate 113. The substrate 113 may be a part of an optical device which operates using the composite 112 as a photoluminescence wavelength tunable material. For example, the substrate 113 may be an active layer located in an upper layer of a solar cell. An active layer of a solar cell has an intrinsic reaction wavelength range. The solar cell exhibits the highest efficiency when light of the wavelength range is incident but exhibits lower efficiency due to generation of heat or perturbation when light of other wavelength is incident.

In an exemplary embodiment, the graphene oxide-metal nanoparticle composite 112 may be configured such that the light emitted from the composite 112, which corresponds to the reaction wavelength range of the active layer, is emitted and incident on the active layer. Since the graphene oxide included in the composite 112 is optically highly transparent, the light emitted from outside may be transferred to the active layer after being controlled to correspond to the reaction wavelength range of the active layer without significant loss of light. Accordingly, the efficiency of the solar cell may be improved while reducing loss.

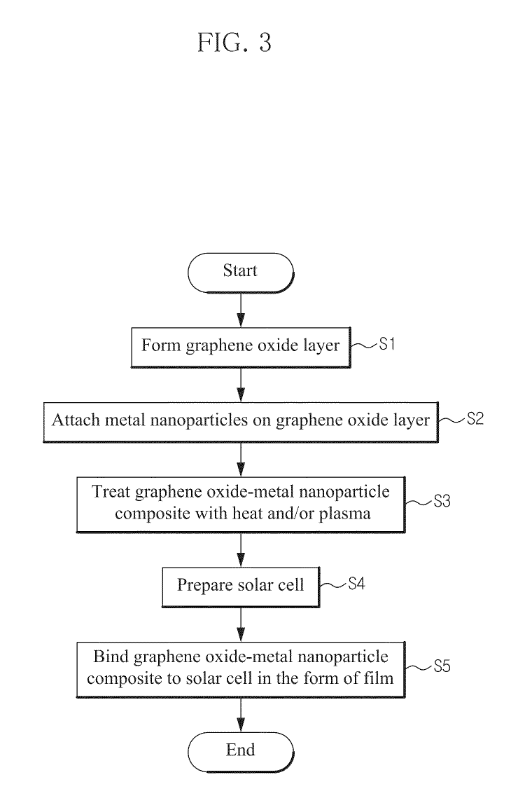

FIG. 3 shows a flowchart illustrating a method for preparing a photoluminescence wavelength tunable solar cell using a composite according to an exemplary embodiment.

Referring to FIG. 3, a graphene oxide layer may be formed first (S1). Then, metal nanoparticles may be attached on the graphene oxide layer (S2). As a result, a graphene oxide-metal nanoparticle composite may be formed. In an exemplary embodiment, the graphene oxide-metal nanoparticle composite may be treated with heat and/or plasma (S3). By changing the physical and/or electrical structure of the composite through the heat and/or plasma treatment, the photoluminescence wavelength of the graphene oxide may be changed as desired.

Meanwhile, a solar cell in which the graphene oxide-metal nanoparticle composite will be used as a photoluminescence wavelength tunable material may be prepared (S4). The solar cell may include an active layer for converting the light incident from the graphene oxide-metal nanoparticle composite into electric energy. Then, the graphene oxide-metal nanoparticle composite may be bound to the solar cell in the form of a film (S5). For example, the graphene oxide-metal nanoparticle composite may be coated on the solar cell, applied in the form of a dispersion or may be bound by a different method.

In FIG. 3, the steps of preparing the solar cell and binding the composite thereto (S4-S5) are shown as separated from the steps of forming the graphene oxide-metal nanoparticle composite (S1-S3). However, this is only exemplary and, in another exemplary embodiment, the graphene oxide layer may be formed on a part (e.g., an active layer) of a solar cell as a substrate in S1. In this case, the steps of preparing the solar cell and binding the composite thereto (S4-S5) may be omitted.

Although application of the photoluminescence wavelength tunable material to a solar cell was described above, the optical device to which the photoluminescence wavelength tunable material of the present disclosure may be applied is not limited to the solar cell. For example, the photoluminescence wavelength tunable material according to the present disclosure may be applied to various optical devices or optoelectronic devices such as light-emitting diodes (LEDs), organic light-emitting diodes (OLEDs), electroluminescence (EL) devices or the like.

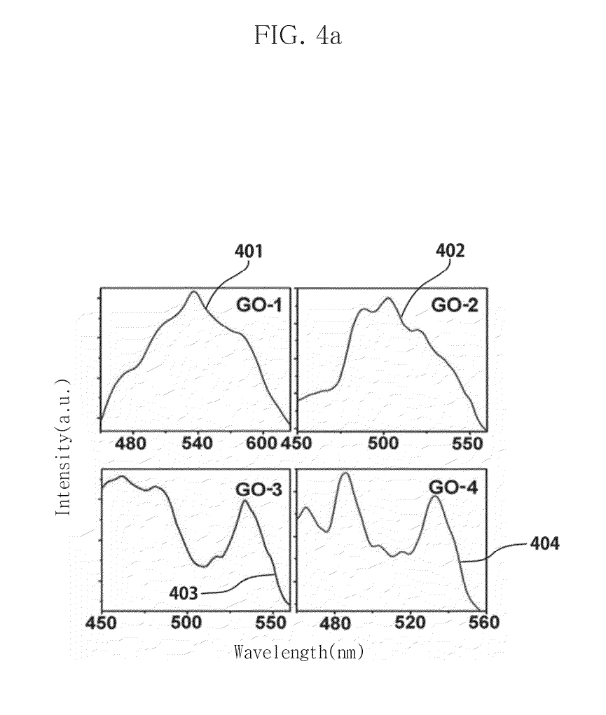

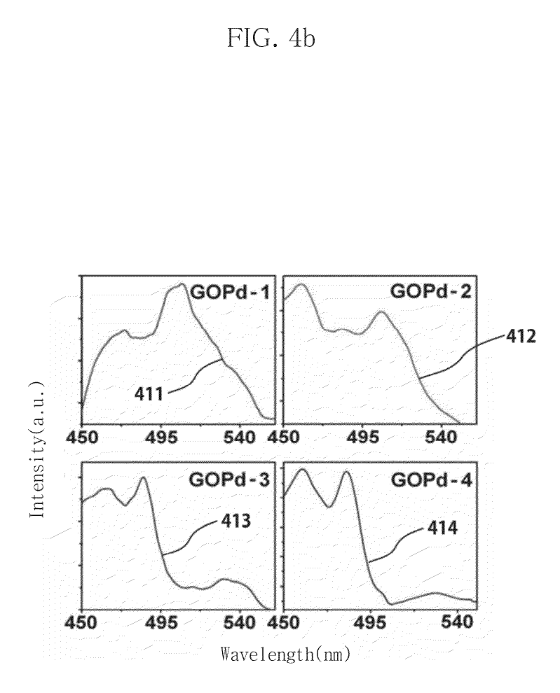

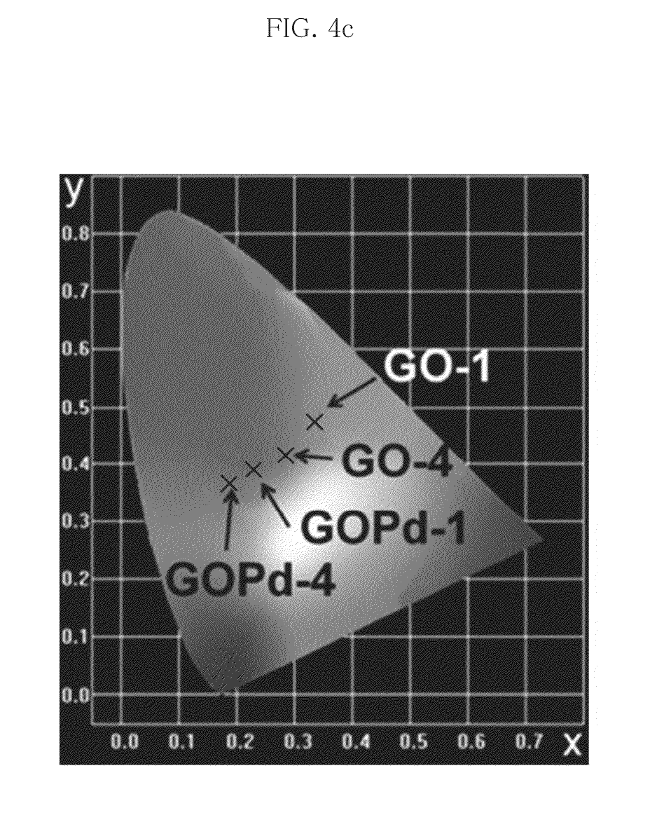

FIG. 4a shows photoluminescence wavelength of graphene oxide samples and FIG. 4b shows photoluminescence wavelength of composites wherein palladium (Pd) nanoparticles are attached to the graphene oxide sample of FIG. 4a.

The four graphs 401, 402, 403, 404 shown in FIG. 4a show the intensity of the light emitted by photoluminescence from four different graphene oxide samples GO-1, GO-2, GO-3, GO-4 depending on wavelength. The color of the light emitted from each sample is determined by the wavelength at which the intensity of each graph 401, 402, 403, 404 is the highest.

The four graphs 411, 412, 413, 414 shown in FIG. 4b show the intensity of the light emitted by photoluminescence from four graphene oxide-metal nanoparticle composites GOPd-1, GOPd-2, GOPd-3, GOPd-4 prepared by attaching palladium (Pd) nanoparticle to the four graphene oxide samples GO-1, GO-2, GO-3, GO-4 depending on wavelength. Similarly to the graphs in FIG. 4b, the color of the light emitted from each composite is determined by the wavelength at which the intensity of each graph 411, 412, 413, 414 is the highest.

To compare FIGS. 4a and 4b, it can be seen that the photoluminescence wavelength is shifted as the palladium (Pd) nanoparticles are attached. For example, to compare the graph 401 for the graphene oxide sample GO-1 with that of the composite GOPd-1 wherein palladium (Pd) nanoparticles are attached to the sample, it can be seen that the photoluminescence wavelength is shifted toward shorter wavelength owing to the palladium (Pd) nanoparticles. Other samples also show shift of the photoluminescence wavelength toward shorter wavelength (i.e., blue shift) as a result of the attachment of the palladium (Pd) nanoparticles. It is because the attachment of the palladium (Pd) nanoparticles leads to increased degree of reduction and thus increased proportion of sp² carbons.

FIG. 4c is a CIE (International Commission on Illumination) chromaticity diagram showing the change in photoluminescence wavelength shown in FIGS. 4a and 4b. As seen from FIG. 4c, the graphene oxide-metal nanoparticle composites GOPd-1, GOPd-4 obtained by attaching palladium (Pd) nanoparticles to graphene oxide exhibit blue shift of the photoluminescence wavelength as compared to the pure graphene oxide samples GO-1, GO-4 with no metal nanoparticles attached. However, this is only exemplary and the change in the photoluminescence wavelength of the photoluminescence wavelength tunable material according to the embodiments is not limited to the above-described examples. For example, the change in the wavelength may be achieved by changing the material of the metal nanoparticles included in the composite or by modifying the structure of the composite through heat and/or plasma treatment.

In accordance with the present disclosure, by providing a photoluminescence wavelength tunable graphene oxide-metal nanoparticle composite, the efficiency of an energy harvesting device such as a solar cell may be improved while reducing loss of light. Also, the graphene oxide-metal nanoparticle composite may be widely applied to various optical devices or optoelectronic devices such as light-emitting diodes (LEDs), organic light-emitting diodes (OLEDs), electroluminescence (EL) devices or the like.

While exemplary embodiments have been shown and described, it will be understood by those skilled in the art that various changes in form and details may be made thereto without departing from the spirit and scope of the present disclosure as defined by the appended claims. In addition, many modifications can be made to adapt a particular situation or material to the teachings of the present disclosure without departing from the essential scope thereof. Therefore, it is intended that the present disclosure not be limited to the particular exemplary embodiments disclosed as the best mode contemplated for carrying out the present disclosure, but that the present disclosure will include all embodiments falling within the scope of the appended claims.

What is claimed is:

1. A photoluminescence wavelength tunable material comprising a composite comprising a graphene oxide layer and metal nanoparticles attached on the graphene oxide layer.

2. The photoluminescence wavelength tunable material according to claim 1, wherein the graphene oxide layer has a photoluminescence characteristic and the photoluminescence wavelength of the graphene oxide layer is determined based on a material of the metal nanoparticles or a structure of the composite.

3. The photoluminescence wavelength tunable material according to claim 1, wherein the metal nanoparticle comprises a metal or a metal oxide.

4. The photoluminescence wavelength tunable material according to claim 3, wherein the metal nanoparticle comprises one or more selected from a group consisting of palladium (Pd), gold (Au), silver (Ag), aluminum (Al), titanium (Ti), chromium (Cr), copper (Cu), europium (Eu) and erbium (Eb).

5. The photoluminescence wavelength tunable material according to claim 3, wherein the metal nanoparticle comprises one or more selected from a group consisting of titanium oxide (TiO₂) and aluminum oxide (Al₂O₃).

6. The photoluminescence wavelength tunable material according to claim 1, wherein the composite is in the form of a film or a dispersion.

7. An optical device comprising the photoluminescence wavelength tunable material according to claim 1.

8. The device according to claim 7,
wherein the optical device is a solar cell, and
wherein the solar cell further comprises an active layer configured to produce electric energy using a light emitted by the photoluminescence wavelength tunable material.

9. A method for preparing a photoluminescence wavelength tunable material, the method comprising:
forming a graphene oxide layer; and
attaching metal nanoparticles to the graphene oxide layer to form a composite comprising the graphene oxide layer and metal nanoparticles.

10. The method according to claim 9, further comprising exposing the composite to heat and/or plasma.

11. The method according to claim 9, further comprising binding the composite to a part of an optical device.

12. The method for preparing a photoluminescence wavelength tunable material according to claim 11, wherein the optical device is a solar cell and the part is an active layer of the solar cell.

13. The method according to claim 9, wherein said forming the graphene oxide layer comprises forming the graphene oxide layer on to a part of an optical device.

14. The method according to claim 13, wherein the optical device is a solar cell and the part is an active layer of the solar cell.
